(19) United States
(12) Patent Application Publication
(10) Pub. No.: US 2025/0002251 A1
(43) Pub. Date: Jan. 2, 2025

(54) Transport Vehicle

(71) Applicant: Daifuku Co., Ltd., Osaka-shi (JP)

(72) Inventor: Kyota Inazumi, Hinocho (JP)

(21) Appl. No.: 18/756,427

(22) Filed: Jun. 27, 2024

(30) Foreign Application Priority Data
Jun. 28, 2023 (JP) 2023-106138

(51) Int. Cl. B65G 1/04

(52) U.S. Cl. CPC B65G 1/0457; B65G 2201/0297

(57) ABSTRACT

A transport vehicle includes a holding device configured to hold a container including a pair of supported portions and a pressed portion. The holding device includes a pair of support portions configured to respectively support the pair of supported portions, and a pressing portion configured to press the pressed portion. The support portion has an inclined support surface, and the pressing portion has an inclined pressing surface.

### CROSS-REFERENCE TO RELATED APPLICATION

This application claims priority to Japanese Patent Application No. 2023-106138 filed Jun. 28, 2023, the disclosure of which is hereby incorporated by reference in its entirety.

### BACKGROUND OF THE INVENTION

### 1. Field of the Invention

The present invention relates to a transport vehicle.

### 2. Description of Related Art

For example, in a semiconductor manufacturing plant or the like, a transport vehicle that transports a container that accommodates a wafer, a reticle, or the like is used. An example of such a transport vehicle is disclosed in Japanese Patent Application Laid-Open No. 2016-163001 (Patent Literature 1). The transport vehicle (transport device 100) of Patent Literature 1 is a ceiling transport vehicle that travels along rails installed on a ceiling, and includes a holding device (gripper device 10) that suspends and holds a container (storage container 50). The holding device has a configuration in which a pair of support portions (grip portions 20) support a pair of supported portions (flange portions 51) provided in the container in a state in which a spherical pressed portion (insertion hole 51a) provided in the container is pressed from above by a pressing portion (center cone 13).

Meanwhile, as the container of a transport target by the transport vehicle, an open-type container called an open cassette, which has no lid body for sealing an opening portion, may be used. In addition, such an open-type container may be transported in a state in which an opening for taking in and out faces obliquely upward in order to prevent an accommodated object from flying out. The pair of support portions provided in the holding device of the transport vehicle of Patent Literature 1 are horizontal support surfaces facing vertically upward, and do not take into account a case in which the container is transported by tilting. In addition, in the holding device of the transport vehicle of Patent Literature 1, it is difficult to stably hold and transport the container only by inclining each of the support surfaces of the pair of support portions.

### SUMMARY OF THE INVENTION

Therefore, there is a demand for a transport vehicle that is able to stably hold and transport the container in a state in which the opening of the container faces obliquely upward. A transport vehicle according to the present disclosure that transports a container including a pair of supported portions and a pressed portion, the transport vehicle including
a holding device configured to hold the container,
in which the holding device includes
a pair of support portions configured to respectively support the pair of supported portions,
a holding drive unit configured to change a posture of the pair of support portions between a holding posture for holding the container and a holding release posture for releasing the holding of the container, and
a pressing portion configured to press the pressed portion,
the support portion has an inclined support surface and supports a supported surface of the supported portion by the inclined support surface,
the pressing portion has an inclined pressing surface and presses a pressed surface of the pressed portion on the inclined pressing surface, and
the inclined pressing surface is provided to be parallel to the pressed surface in a state in which the supported surface is supported by the inclined support surface.

According to this configuration, by putting the pair of support portions in the holding posture, the supported surface of the supported portion is supported by the pair of inclined support surfaces, and the container is able to be supported in a posture in which the opening for taking in and out an accommodated object faces obliquely upward. In this case, the pressed surface is able to be pressed in a direction orthogonal thereto by the inclined pressing surface parallel to the pressed surface in a state in which the supported surface is supported by the inclined support surface of the support portion. As a result, the container is able to be held from both the upper and lower sides by the mutually parallel inclined support surface and inclined pressing surface. Therefore, the container is able to be stably held and transported in a state in which the opening of the container faces obliquely upward.

Further features and advantages of the technique according to the present disclosure will be more clearly understood from the following exemplary and non-limiting description of the embodiments with reference to the accompanying drawings.

### BRIEF DESCRIPTION OF THE DRAWINGS

FIG. 1 is a perspective view of a transport vehicle according to an embodiment;

FIG. 2 is a front view of the transport vehicle;

FIG. 3 is a front view of a container;

FIG. 4 is a side view of the container;

FIG. 5 is a plan view of a holding device;

FIG. 6 is a front view of the holding device;

FIG. 7 is a view illustrating a posture change of a support portion and a shielding member;

FIG. 8 is a plan view of the holding device;

FIG. 9 is a side view of the holding device;

FIG. 10 is a front view of the holding device;

FIG. 11 is a front view (partially cross-section) illustrating structures of a pressing support mechanism and a detection device; and

FIG. 12 is a side view (partially cross-section) illustrating structures of the pressing support mechanism and the detection device.

### DESCRIPTION OF THE INVENTION

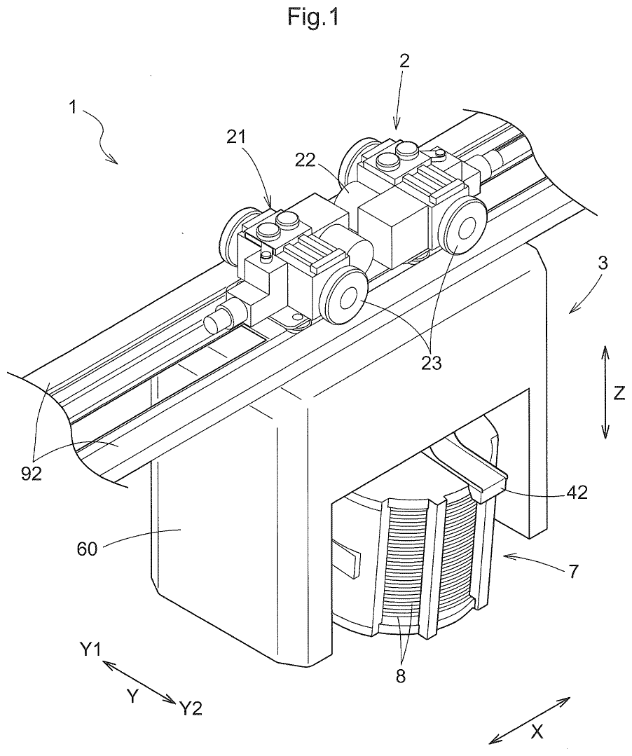

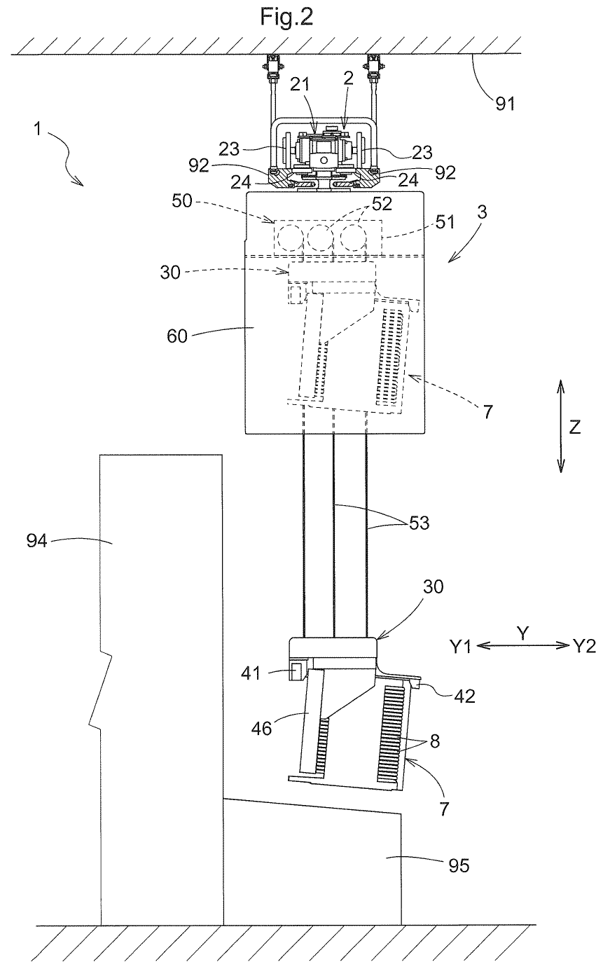

An embodiment of a transport vehicle will be described with reference to the drawings. A transport vehicle 1 according to the present embodiment is used, for example, to transport a container 7 in a semiconductor manufacturing plant or the like. As illustrated in FIGS. 1 and 2, the transport vehicle 1 includes a travel unit 2 that travels along a movement path, and a transfer mechanism 3 connected to the travel unit 2. In the present embodiment, the movement path of the transport vehicle 1 is physically formed by rails 92 that are suspended and supported from a ceiling 91. That is, the transport vehicle 1 according to the present embodiment is a ceiling transport vehicle that moves along the rails 92 formed along the ceiling 91.

The travel unit 2 travels along a pair of rails 92. The travel unit 2 includes a vehicle body 21, a travel drive unit 22, wheels 23, and guide wheels 24. The vehicle body 21 supports the travel drive unit 22, the wheels 23, the guide wheels 24, and the like. The travel drive unit 22 includes, for example, an electric motor such as a servo motor, and drives at least one of the wheels 23. The wheel 23 rolls on an upper surface of the rail 92. The wheel 23 that is drivingly connected to the travel drive unit 22 functions as a drive wheel. The guide wheel 24 rolls on an inner side surface of the rail 92. The travel unit 2 travels on the rails 92 along the rails 92 in a state in which the guide wheels 24 come into contact with and guided by the inner side surfaces of the rails 92.

In the following description, a direction along an extension direction of the rail 92, which is a direction in which the travel unit 2 travels, is referred to as a front-rear direction X of the transport vehicle 1. In addition, a direction orthogonal to the front-rear direction X and a direction along an arrangement direction of the pair of rails 92 is referred to as a width direction Y of the transport vehicle 1. In addition, a direction orthogonal to both the front-rear direction X and the width direction Y is referred to as an up-down direction Z. Each of these directions is a direction with the transport vehicle 1 as a reference, and the front-rear direction X and the width direction Y may vary depending on a position of the transport vehicle 1 along the movement path in a case of being viewed from a fixed point in a facility.

The transfer mechanism 3 is disposed below the rails 92 and is connected to the travel unit 2. The transfer mechanism 3 includes a holding device 30, a lifting and lowering device 50, and a cover body 60. The holding device 30 is a device for holding the container 7. The lifting and lowering device 50 is a device for lifting and lowering the holding device 30. The lifting and lowering device 50 lifts and lowers the holding device 30 between a lifted position illustrated by a broken line and a lowered position illustrated by a solid line in FIG. 2. The cover body 60 accommodates the lifting and lowering device 50 and the holding device 30 in the lifted position. An inside space of the cover body 60 is shielded on both sides in the front-rear direction X, and at least one side (in the present example, both sides) in the width direction Y is open.

The transport vehicle 1, for example, the travel unit 2 travels to a position of a target processing device 94 in a state in which the holding device 30 holds the container 7, and as illustrated in FIG. 2, the lifting and lowering device 50 lowers the holding device 30 to the lowered position to transport the container 7 to the target processing device 94. FIG. 2 illustrates an example in which the container 7 is placed on a placing table 95 disposed adjacent to the processing device 94 to supply the container 7 to the target processing device 94. In addition, the transport vehicle 1 is able to transport the container 7 out of the processing device 94 in which processing is terminated by performing an operation opposite to the above description.

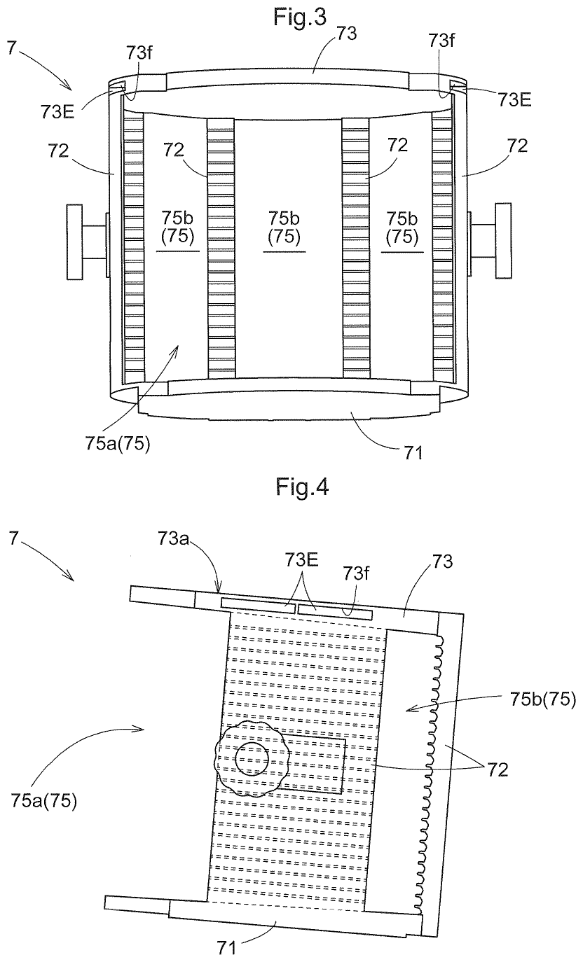

As illustrated in FIGS. 3 and 4, the container 7, which is a transport object by the transport vehicle 1 according to the present embodiment, includes a bottom plate 71, a side wall 72, and an inclined top plate 73. These are integrally formed. The bottom plate 71 is a support plate provided at a lower end portion of the container 7, and is formed in a circular shape in the present embodiment. The side wall 72 extends upward from an outer edge of the bottom plate 71 and is formed in a cylindrical shape having an opening 75 in the present embodiment. The inclined top plate 73 is provided at an upper end portion of the side wall 72 and is formed in a circular shape similar to the bottom plate 71 in the present embodiment. In the present embodiment, the inclined top plate 73 is provided to be non-parallel to the bottom plate 71, in other words, inclined with respect to the bottom plate 71. A degree of inclination of the inclined top plate 73 with respect to the bottom plate 71 may be very small, and an inclination angle may be, for example, 1° to 10°.

In the present embodiment, a concave portion 73E that is recessed inward with respect to the side wall 72 is formed on an outer edge side of the inclined top plate 73. The concave portion 73E is formed at two locations which are different in the circumferential direction of the inclined top plate 73 (specifically, at two locations that are opposite to each other with a center of the container 7 interposed therebetween). The container 7 is supported from below by support portions 32 provided in the holding device 30 of the transport vehicle 1 at the concave portions 73E on the outer edge side of the inclined top plate 73. More specifically, the container 7 is supported from below by a pair of support portions 32 provided in the holding device 30 of the transport vehicle 1, with a pair of concave portions 73E formed on the outer edge side of the inclined top plate 73. In the present embodiment, the concave portion 73E formed in the inclined top plate 73 corresponds to the “supported portion”. A surface of an inside of the concave portion 73E of the inclined top plate 73 facing downward is a supported surface 73f actually supported by the support portion 32. In the present embodiment, the inside of the concave portion 73E is formed such that the supported surface 73f is not parallel to an upper surface 73a.

In addition, the container 7 is held by the holding device 30 in a state in which the upper surface 73a of the inclined top plate 73 is pressed by a pressing portion 35 provided in the holding device 30. In the present embodiment, the inclined top plate 73 corresponds to a “pressed portion”, and the upper surface 73a of the inclined top plate 73 corresponds to a “pressed surface”.

As described above, the container 7 according to the present embodiment has the opening 75 in the side wall 72. In the present embodiment, the opening 75 includes a front opening 75a formed on the front side and a rear opening 75b formed on the rear side. The front opening 75a is formed with a large width of the opening, and is formed with a width wider than at least a maximum width of an accommodated object 8. The rear opening 75b is formed with a smaller width than the front opening 75a, and is formed with a width narrower than the maximum width of the accommodated object 8. In the present embodiment, three rear opening portions 75b are formed side by side to be spaced apart from each other at predetermined intervals.

The accommodated object 8 accommodated in the container 7 is taken in and out from the front opening 75a. That is, among the openings 75 formed in the side wall 72, the front opening 75a serves as an opening for taking in and out the accommodated object 8. Examples of the accommodated object 8 include a semiconductor wafer, a reticle, and the like. The container 7 is configured to be capable of accommodating a plurality of accommodated objects 8 side by side vertically. In addition, the container 7 according to the present embodiment does not include a lid for closing the opening 75, and an open cassette is able to be used, for example.

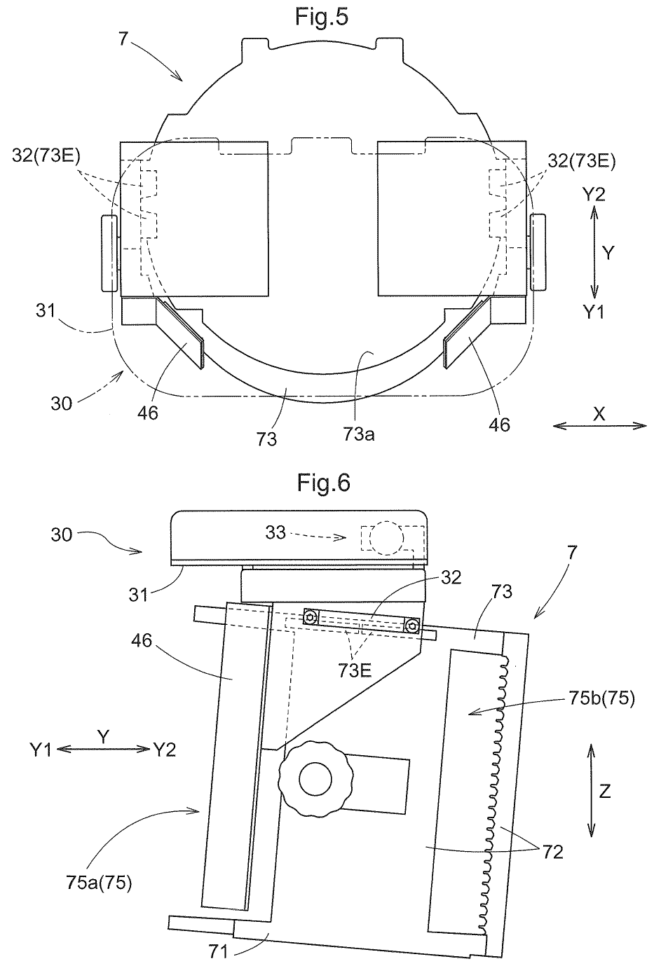

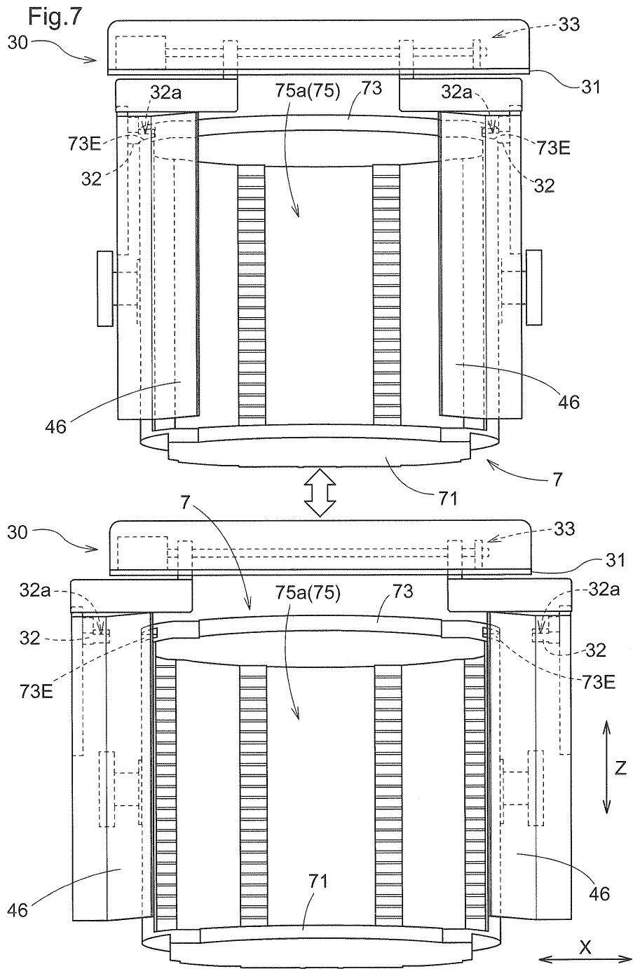

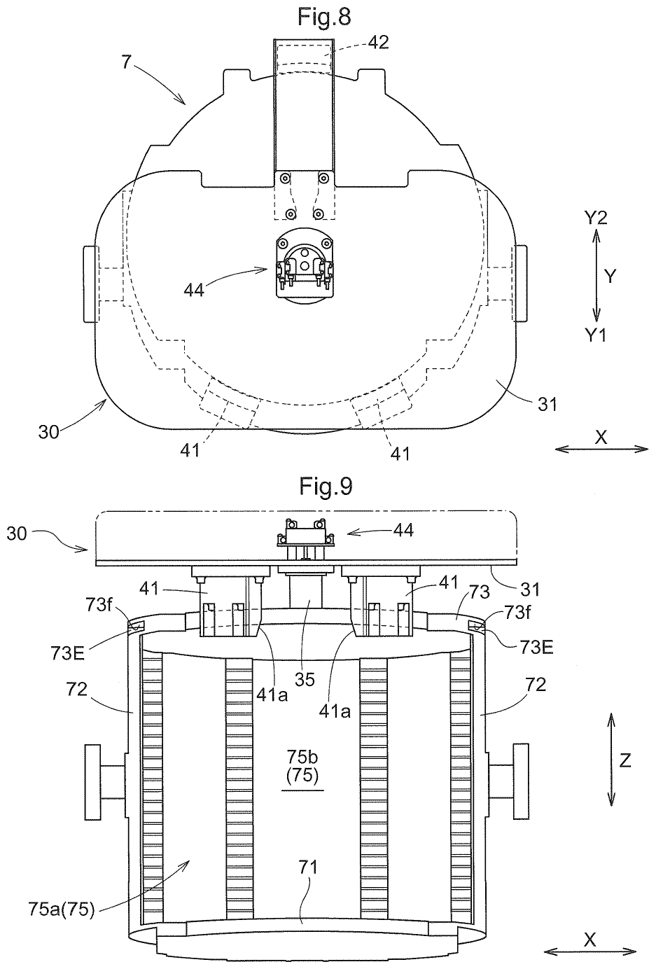

Returning to the description of the transport vehicle 1, the holding device 30 constituting the transfer mechanism 3 includes a holding main body portion 31, the support portions 32, a holding drive unit 33, the pressing portion 35, and a pressing support mechanism 36, as illustrated in FIGS. 5 to 10. In addition, the holding device 30 includes a first guide portion 41, a second guide portion 42, a detection device 44, and a shielding member 46. FIGS. 5 to 7 are mainly views focusing on the support portion 32 and the shielding member 46, and the display of other components is appropriately omitted for considering case of viewing. In addition, FIGS. 8 to 10 are mainly views focusing on the pressing portion 35, the first guide portion 41, and the second guide portion 42, and the display of other components is appropriately omitted for considering case of viewing.

The holding main body portion 31 is a portion serving as a base of the holding device 30. The holding main body portion 31 supports the support portion 32 and the shielding member 46 to be slidable in the front-rear direction X. In addition, the holding main body portion 31 fixedly supports the holding drive unit 33 and the detection device 44 on the upper surface side thereof. In addition, the holding main body portion 31 slidably supports the pressing portion 35 in the up-down direction Z. In addition, the holding main body portion 31 fixedly supports the pressing support mechanism 36, the first guide portion 41, and the second guide portion 42 on the lower surface side thereof.

The support portion 32 supports the concave portion 73E of the inclined top plate 73 of the container 7. In the present embodiment, the pair of support portions 32 are provided to be able to simultaneously support the pair of concave portions 73E at different positions in the circumferential direction of the inclined top plate 73. The pair of support portions 32 are provided side by side in the front-rear direction X with predetermined intervals therebetween. The pair of support portions 32 are each configured to be slidable in the front-rear direction X, and are driven by the holding drive unit 33 to move close to each other in the front-rear direction X or to move separated from each other in the front-rear direction X.

In the present embodiment, the front-rear direction X, which is the direction in which the pair of support portions 32 are arranged when viewed in the up-down direction, corresponds to a “first direction”. In addition, the width direction Y, which is a direction orthogonal to the front-rear direction X as the first direction when viewed in the up-down direction, corresponds to a “second direction”. In addition, in the following description, one side (for example, the left side in FIG. 2) of the width direction Y as the second direction is referred to as a “first side Y1” in the width direction, and the other side of the width direction Y, which is opposite to the one side, is referred to as a “second side Y2 in the width direction”. In the present embodiment, the width direction first side Y1 corresponds to a “first side in the second direction”, and the width direction second side Y2 corresponds to a “second side in the second direction”.

In the present embodiment, the support portion 32 has an inclined support surface 32a facing obliquely upward. The inclined support surface 32a is formed on a flat surface and is disposed such that an end portion on the first side Y1 in the width direction is located at an upper side compared to an end portion on the second side Y2 in the width direction. The support portion 32 is able to support the supported surface 73f inside the concave portion 73E formed on the inclined top plate 73 of the container 7 from the lower side on the inclined support surface 32a.

The holding drive unit 33 moves the pair of support portions 32 in the front-rear direction X. The holding drive unit 33 is configured to include, for example, a holding electric motor and a mechanism (for example, a ball screw mechanism) that converts the rotation of the holding electric motor into the propulsion force in the front-rear direction X. The holding drive unit 33 moves the pair of support portions 32 in opposite directions to each other to move the support portions 32 to be close to each other in the front-rear direction X or to move the support portions 32 to be separated from each other in the front-rear direction X. In a case in which the holding drive unit 33 includes the ball screw mechanism, helical directions of a screw shaft is formed to be opposite to each other on one side and the other side in the front-rear direction X, so that the above-described proximity movement and separation movement are able to be performed only by the single holding electric motor.

The holding drive unit 33 is able to be in a holding posture in which the container 7 is held by supporting the concave portion 73E of the inclined top plate 73 by moving the pair of support portions 32 close to each other in the front-rear direction X. In addition, the holding drive unit 33 is able to be in a holding release posture in which the holding of the container 7 is released by separating from the concave portion 73E of the inclined top plate 73 by moving the pair of support portions 32 separated from each other in the front-rear direction X. As described above, the holding drive unit 33 is able to change the posture of the pair of support portions 32 between the holding posture and the holding release posture.

The pressing portion 35 presses the inclined top plate 73 of the container 7. The pressing portion 35 is disposed between the pair of support portions 32 in the front-rear direction X. In the present embodiment, the pressing portion 35 has an inclined pressing surface 35a facing obliquely downward. The inclined pressing surface 35a is formed on the flat surface and is disposed such that the end portion on the first side Y1 in the width direction is located on the upper side compared to the end portion on the second side Y2 in the width direction. In the present embodiment, the inclined pressing surface 35a is similarly disposed in a non-parallel to the inclined support surface 32a of the support portion 32 that is inclined such that the end portion on the first side Y1 in the width direction is located on the upper side compared to the end portion on the second side Y2 in the width direction.

The pressing portion 35 presses the upper surface 73a of the inclined top plate 73 of the container 7 from the upper side with the inclined pressing surface 35a. As described above, the concave portion 73E of the inclined top plate 73 of the container 7 is formed such that the supported surface 73f inside thereof is in a non-parallel to the upper surface 73a. In the present embodiment, an inclination angle of the inclined pressing surface 35a of the pressing portion 35 with respect to the inclined support surface 32a of the support portion 32 and an inclination angle of the upper surface 73a of the inclined top plate 73 with respect to the supported surface 73f of the concave portion 73E of the container 7 are provided to be equal to each other. As a result, the inclined pressing surface 35a of the pressing portion 35 is provided to be parallel to the upper surface 73a of the inclined top plate 73 in a state in which the supported surface 73f of the concave portion 73E is supported by the inclined support surface 32a of the support portion 32. Therefore, the inclined pressing surface 35a is pressed against the upper surface 73a of the inclined top plate 73 from above in a state in which the supported surface 73f inside the concave portion 73E of the inclined top plate 73 is supported by the inclined support surface 32a.

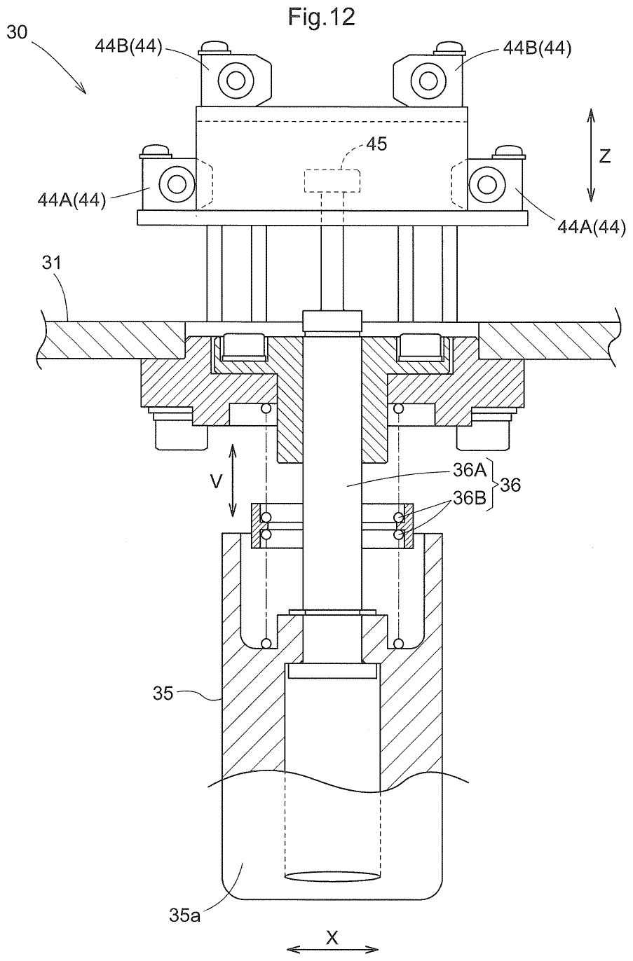

The pressing support mechanism 36 (see FIGS. 11 and 12) supports the pressing portion 35 to be movable in a movable direction V with respect to the holding main body portion 31. In the present embodiment, the up-down direction Z is the movable direction V, and the pressing support mechanism 36 supports the pressing portion 35 to be movable in the up-down direction Z with respect to the holding main body portion 31. The pressing support mechanism 36 includes a shaft portion 36A that extends upward from the pressing portion 35 along the up-down direction Z, and an clastic member 36B that is disposed between the holding main body portion 31 and the pressing portion 35.

The shaft portion 36A is inserted into a through-hole formed in the holding main body portion 31 in a slidable state along the up-down direction Z. The shaft portion 36A plays a role of a guide that guides the movement of the pressing portion 35 along the up-down direction Z (movable direction V). As the clastic member 36B, for example, a coil spring, a leaf spring, or the like is able to be used. In the present embodiment, the coil spring is used as the elastic member 36B. The clastic member 36B biases the pressing portion 35 downward in a compressed state by an clastic restoring force. As described above, the pressing support mechanism 36 supports the pressing portion 35 such that the pressing portion 35 is biased downward. Here, in particular, in the pressing support mechanism 36, the elastic member 36B is in a compressed state to bias the pressing portion 35 downward in a state in which the inclined support surface 32a abuts against the upper surface 73a while supporting the concave portion 73E of the inclined top plate 73 by the pair of support portions 32.

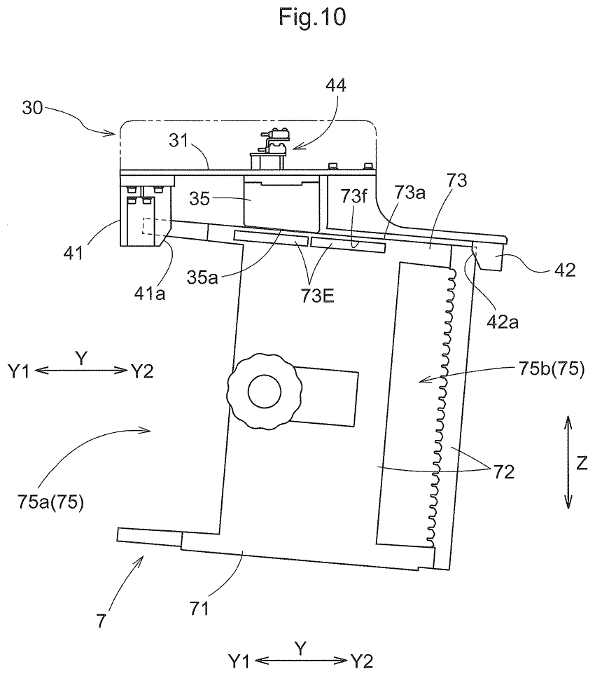

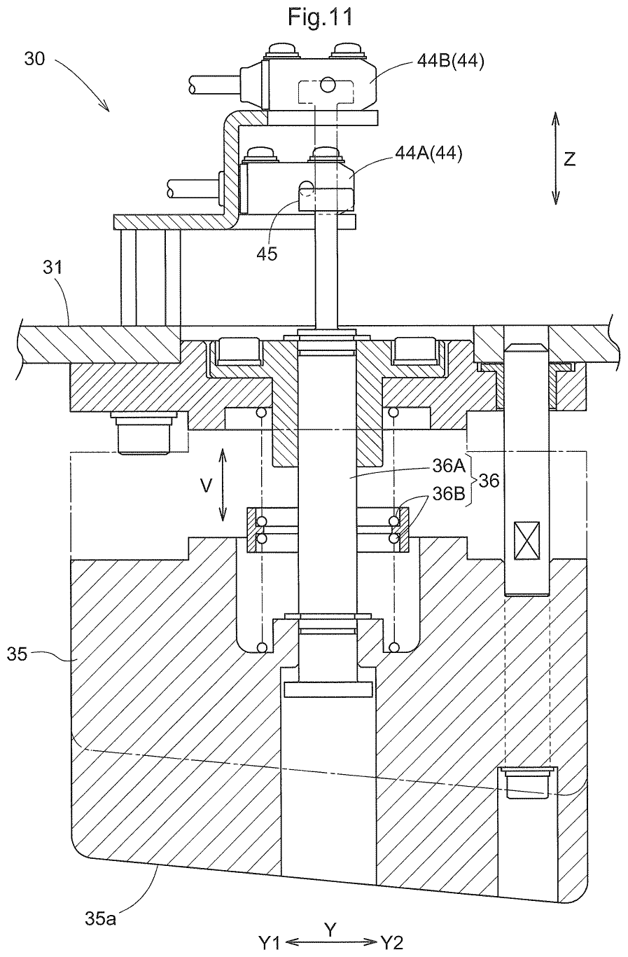

As illustrated in FIGS. 8 to 10, the first guide portion 41 is fixed to the holding main body portion 31 in the vicinity of the end portion of the first side Y1 in the width direction. In FIGS. 8 to 10, although the display of the support portion 32 is omitted for considering case of viewing, as easily understood from FIG. 10, the first guide portion 41 is disposed on the first side Y1 in the width direction with respect to the support portion 32 that supports the concave portion 73E of the inclined top plate 73 of the container 7. In addition, in the present embodiment, a plurality (two in the present example) of first guide portions 41 is provided to be separated along an arc-shaped surface when viewed in the up-down direction. The plurality of first guide portions 41 are provided at positions symmetrical to a center portion of the holding device 30 in the front-rear direction X. The first guide portion 41 is disposed to be able to abut against the inclined top plate 73 of the container 7 from the first side Y1 in the width direction, and the container 7 is positioned in the width direction Y by the first guide portion 41 and the second guide portion 42 in cooperation with each other.

The first guide portion 41 has a first guide surface 41a on a side surface of the second side Y2 in the width direction which faces the inclined top plate 73 of the container 7. The first guide surface 41a is formed in a tapered shape that is inclined toward the second side Y2 in the width direction as going upward. The first guide portion 41 has such a first guide surface 41a, so that in a case in which the holding device 30 is deviated to the second side Y2 in the width direction with respect to the container 7 during the lowering of the holding device 30, the position of the holding device 30 in the width direction Y is able to be corrected to the first side Y1 in the width direction.

The second guide portion 42 is fixed to the vicinity of an end portion of a bracket that is fixed to the holding main body portion 31 on the second side Y2 in the width direction and extends on the second side Y2 in the width direction. The second guide portion 42 is disposed on the second side Y2 in the width direction with respect to the support portion 32 that supports the concave portion 73E of the inclined top plate 73 of the container 7. In the present embodiment, only one second guide portion 42 is provided, and is disposed at the center portion of the holding device 30 in the front-rear direction X. The second guide portion 42 is disposed to be able to abut against the inclined top plate 73 of the container 7 from the second side Y2 in the width direction, and the container 7 is positioned in the width direction Y by the first guide portion 41 and the second guide portion 42 in cooperation with each other.

The second guide portion 42 has a second guide surface 42a on a side surface of the first side Y1 in the width direction which faces the inclined top plate 73 of the container 7. The second guide surface 42a is formed in a tapered shape that is inclined toward the first side Y1 in the width direction as going upward. The second guide portion 42 has such a second guide surface 42a, so that in a case in which the holding device 30 is deviated to the first side Y1 in the width direction with respect to the container 7 during the lowering of the holding device 30, the position of the holding device 30 in the width direction Y is able to be corrected to the second side Y2 in the width direction.

In this way, in a case in which the holding device 30 is lowered to approach the container 7 from the upper side, any one of the first guide surface 41a of the first guide portion 41 and the second guide surface 42a of the second guide portion 42 comes into contact with the container 7, and the position of the holding device 30 in the width direction Y is corrected. In a case in which there is no deviation in the position of the holding device 30 in the width direction Y with respect to the container 7, both the first guide surface 41a and the second guide surface 42a may not come into contact with the container 7.

The first guide portion 41 and the second guide portion 42 are disposed at different positions in the up-down direction Z. In the present embodiment, as illustrated in FIG. 10, the first guide portion 41 disposed on the first side Y1 in the width direction is disposed on the upper side in the up-down direction Z with respect to the second guide portion 42 disposed on the second side Y2 in the width direction. Such a configuration is suitable for a configuration in which the holding device 30 supports the container 7 in a posture in which the front opening 75a for taking in and out the accommodated object 8 faces obliquely upward.

The detection device 44 detects whether the holding device 30 is within a holding proper range based on the position of the pressing portion 35 in the movable direction V (in the present embodiment, the up-down direction Z). Here, the holding proper range is a range of the position of the holding device 30 in the up-down direction Z in which the pair of support portions 32 are able to support the concave portion 73E of the inclined top plate 73 by changing from the holding release posture to the holding posture. In the present embodiment, since the pair of support portions 32 are slidably moved in the front-rear direction X and are changed from the holding release posture to the holding posture, the holding proper range is a range of the position of the holding device 30 in the up-down direction Z in which the entire support portion 32 is accommodated in the concave portion 73E of the inclined top plate 73.

As illustrated in FIGS. 11 and 12, in the present embodiment, the detection device 44 includes two position sensors disposed at different positions in the up-down direction Z, that is, a first position sensor 44A and a second position sensor 44B. The first position sensor 44A is installed above the pressing support mechanism 36 at a position slightly above and separated from the holding main body portion 31. The second position sensor 44B is installed above the pressing support mechanism 36 at a position further above and separated from the first position sensor 44A.

The first position sensor 44A and the second position sensor 44B according to the present embodiment are each configured of an optical sensor including a light projecting portion and a light receiving portion. In the present embodiment, a detection target 45 is integrally connected to the shaft portion 36A constituting the pressing support mechanism 36 to extend upward from the shaft portion 36A. The detection target 45 is disposed between the light projecting portion and the light receiving portion in the front-rear direction X of each of the first position sensor 44A and the second position sensor 44B. The detection target 45 moves in the up-down direction Z by being interlocked to the movement of the pressing portion 35 in the up-down direction Z.

In the present embodiment, in a state in which the holding device 30 does not hold the container 7, the pressing portion 35 is biased by the pressing support mechanism 36 to the lower end side within the movable range, and in this state, the detection target 45 is not detected by the first position sensor 44A and the second position sensor 44B. In a state in which the holding device 30 holds the container 7, the pressing portion 35 is biased downward by the pressing support mechanism 36 and moves upward within the movable range, and in this state, the detection target 45 is detected by the first position sensor 44A. Therefore, the first position sensor 44A is able to detect whether the holding device 30 holds the container 7 based on the presence or absence of the detection of the detection target 45 (that is, a stock state).

In addition, in the present embodiment, in a case in which the holding device 30 is lowered to approach the container 7 from the upper side, in a case in which the holding device 30 is lowered too much with respect to the container 7 and deviates from the holding proper range, the detection target 45 is also detected by the second position sensor 44B. As a result, the second position sensor 44B is able to detect whether the holding device 30 is located within the holding proper range based on the presence or absence of the detection of the detection target 45.

In a case in which it is determined that the holding device 30 is not located within the holding proper range, the position of the holding device 30 in the up-down direction Z is able to be adjusted by driving the lifting and lowering device 50.

The shielding member 46 partially covers the front opening 75a of the container 7 in a state in which the holding device 30 holds the container 7. In the present embodiment, a pair of shielding members 46 are provided to partially cover regions on both sides of the front opening 75a of the container 7 in the front-rear direction X. The pair of shielding members 46 are configured to change the posture between a closed posture and an opened posture. Here, the closed posture is a posture in which the pair of shielding members 46 face the front opening 75a at least partially in a state in which the pair of support portions 32 support the concave portion 73E of the inclined top plate 73. The opened posture is a posture in which the pair of shielding members 46 do not face the front opening 75a in a state in which the pair of support portions 32 support the concave portion 73E of the inclined top plate 73.

In the present embodiment, the shielding member 46 is integrally connected to a support bracket to which the support portion 32 is fixed. One of the pair of shielding members 46 is connected to one of the pair of support portions 32 via a first support bracket, and these are interlocked to each other to be movable in the front-rear direction X. In addition, the other of the pair of shielding members 46 is connected to the other of the pair of support portions 32 via a second support bracket, and these are interlocked to each other to be movable in the front-rear direction X. The pair of shielding members 46 are configured to be in the closed posture as the pair of support portions 32 are in the holding posture and to be in the opened posture as the pair of support portions 32 are in the holding release posture by being interlocked to the posture change of the pair of support portions 32. The pair of shielding members 46 prevent the accommodated object 8 from slipping out of the container 7 in the closed posture.

The lifting and lowering device 50 lifts and lowers the holding device 30. As illustrated in FIG. 2, the lifting and lowering device 50 includes a lifting and lowering main body portion 51, lifting and lowering drive units 52, and wires 53. The lifting and lowering main body portion 51 is a portion serving as a base of the lifting and lowering device 50. The lifting and lowering main body portion 51 fixedly supports the lifting and lowering drive unit 52 on an upper surface side thereof. The lifting and lowering drive unit 52 is configured to include, for example, a lifting and lowering electric motor and a winding portion that rotates integrally with the lifting and lowering electric motor. One end of the wire 53 is connected to the winding portion constituting the lifting and lowering drive unit 52, and the other end thereof is connected to the holding device 30. The lifting and lowering device 50 lifts and lowers the holding device 30 between the lifted position and the lowered position by driving the lifting and lowering drive unit 52 to wind or unwind the wire.

### OTHER EMBODIMENTS

(1) In the above-described embodiment, the configuration is described as an example in which a case in which the holding device 30 is lowered to approach the container 7 from the upper side, except for a case in which there is no deviation, only one of the first guide surface 41a of the first guide portion 41 and the second guide surface 42a of the second guide portion 42 comes into contact with the container 7. However, the configuration is not limited to this, and both the first guide surface 41a of the first guide portion 41 and the second guide surface 42a of the second guide portion 42 may come into contact with the container 7 to position the container 7 in the width direction Y.

(2) In the above-described embodiment, the configuration is described as an example in which the holding device 30 includes the first guide portion 41 and the second guide portion 42. However, the configuration is not limited to this, and the holding device 30 may not include the first guide portion 41 and the second guide portion 42.

(3) In the above-described embodiment, the configuration is described as an example in which the pressing support mechanism 36 supports the pressing portion 35 to be movable in the up-down direction Z with respect to the holding main body portion 31 (in other words, the up-down direction Z is the movable direction V). However, the configuration is not limited to this, and the movable direction V may be a direction that is slightly inclined with respect to the up-down direction Z. For example, the pressing support mechanism 36 may support the pressing portion 35 with respect to the holding main body portion 31 to be movable in the movable direction V that is inclined at an angle of 10° or less with respect to the up-down direction Z.

(4) In the above-described embodiment, the configuration is described as an example in which the holding device 30 includes the pressing support mechanism 36 that supports the pressing portion 35 to be movable in the movable direction V with respect to the holding main body portion 31. However, the configuration is not limited to this, and the holding device 30 may not include the pressing support mechanism 36.

(5) In the above-described embodiment, the configuration is described as an example in which the detection device 44 includes the first position sensor 44A and the second position sensor 44B. However, the configuration is not limited to this, and the detection device 44 may be configured by using only one of the first position sensor 44A and the second position sensor 44B. Alternatively, the holding device 30 may not include the detection device 44.

(6) In the embodiment described above, the configuration is described as an example in which the pair of shielding members 46 are configured to be in the closed posture as the pair of support portions 32 are in the holding posture and to be in the opened posture as the pair of support portions 32 are in the holding release posture by being interlocked to the posture change of the pair of support portions 32. However, the configuration is not limited to this, and the pair of the shielding members 46 and the pair of the support portions 32 may be separately driven to independently change the posture.

(7) In the above-described embodiment, the configuration is described as an example in which the holding device 30 includes the shielding member 46 that partially covers the front opening 75a of the container 7. However, the configuration is not limited to this, and the holding device 30 may not include the shielding member 46.

(8) In the above-described embodiment, the configuration is described as an example in which the pair of support portions 32 are provided side by side in the front-rear direction X. However, the configuration is not limited to this, and the pair of support portions 32 may be provided side by side in the width direction Y. In this case, the width direction Y corresponds to the “first direction”, and the front-rear direction X corresponds to the “second direction”. The first guide portion 41 and the second guide portion 42 are provided to be separated on both sides in the front-rear direction X with respect to the pair of support portions 32. Alternatively, the pair of support portions 32 may be provided side by side in a direction intersecting both the front-rear direction X and the width direction Y. The “first direction” and the “second direction” or installation positions of the first guide portion 41 and the second guide portion 42 are determined according to an arrangement direction of the pair of support portions 32.

(9) In the above-described embodiment, the configuration is described as an example in which the holding drive unit 33 includes the holding electric motor and the mechanism that converts the rotation of the holding electric motor into the propulsion force in the front-rear direction X. However, the configuration is not limited to this, and the holding drive unit 33 may be configured to include, for example, a mechanism that directly generates the propulsion force in the front-rear direction X, such as a fluid pressure cylinder mechanism.

(10) In the above-described embodiment, the configuration is described as an example in which the holding device 30 supports the concave portion 73E formed on the inclined top plate 73 of the container 7 with the pair of support portions 32. However, the configuration is not limited to this, and for example, the inclined top plate 73 of the container 7 may be formed to protrude outward in a flange shape from the side wall 72, and the holding device 30 may support the flange-shaped protruding portion of the inclined top plate 73 with the pair of support portions 32. In this case, two different locations in the circumferential direction of the flange-shaped protruding portion of the inclined top plate 73 correspond to the “supported portion”. In addition, a handle-like protruding portion may be provided on the side wall 72 of the container 7 at a position different from the inclined top plate 73 in the up-down direction, and the holding device 30 may support the handle-like protruding portion with the pair of support portions 32. In this case, the handle-like protruding portion corresponds to the “supported portion”. The handle-like protruding portion may be integrally formed with the side wall 72, or may be formed of a separate member from the side wall 72 and fixed to the side wall 72.

(11) In the above-described embodiment, the configuration is described as an example in which the supported surface 73f inside the concave portion 73E of the container 7 and the upper surface 73a of the inclined top plate 73 are formed to be non-parallel to each other. However, the configuration is not limited to this, and the supported surface 73f and the upper surface 73a may be formed in parallel to each other. In this case, on the holding device 30 side, the inclined pressing surface 35a of the pressing portion 35 and the inclined support surface 32a of the support portion 32 are formed in parallel to each other. In any case, the inclined pressing surface 35a of the pressing portion 35 is parallel to the upper surface 73a of the inclined top plate 73 in a state in which the supported surface 73f of the concave portion 73E is supported by the inclined support surface 32a of the support portion 32.

(12) In the above-described embodiment, the configuration is described as an example in which an open cassette that does not include a lid for closing the opening 75 is used as the container 7. However, the configuration is not limited to this, and the container 7 (for example, a FOUP, a reticle pod, or the like) provided with a lid for closing the opening 75 may be used.

(13) The configurations disclosed in each of the above-described embodiments (including the above-described embodiments and other embodiments; the same applies hereinafter) are also able to be applied in combination with the configurations disclosed in other embodiments as long as there is no contradiction. Even for other configurations, the embodiments disclosed in the present specification are merely examples in all respects, and are able to be appropriately modified within a range not departing from the gist of the present disclosure.

### SUMMARY OF EMBODIMENTS

In summary, the transport vehicle according to the present disclosure suitably includes the following configurations.

A transport vehicle that transports a container including a pair of supported portions and a pressed portion, the transport vehicle including
a holding device configured to hold the container,
in which the holding device includes
a pair of support portions configured to respectively support the pair of supported portions,
a holding drive unit configured to change a posture of the pair of support portions between a holding posture for holding the container and a holding release posture for releasing the holding of the container, and
a pressing portion configured to press the pressed portion,
the support portion has an inclined support surface and supports a supported surface of the supported portion by the inclined support surface,
the pressing portion has an inclined pressing surface and presses a pressed surface of the pressed portion on the inclined pressing surface, and
the inclined pressing surface is provided to be parallel to the pressed surface in a state in which the supported surface is supported by the inclined support surface.

According to this configuration, by putting the pair of support portions in the holding posture, the supported surface of the supported portion is supported by the pair of inclined support surfaces, and the container is able to be supported in a posture in which the opening for taking in and out an accommodated object faces obliquely upward. In this case, the pressed surface is able to be pressed in a direction orthogonal thereto by the inclined pressing surface parallel to the pressed surface in a state in which the supported surface is supported by the inclined support surface of the support portion. As a result, the container is able to be held from both the upper and lower sides by the mutually parallel inclined support surface and inclined pressing surface. Therefore, the container is able to be stably held and transported in a state in which the opening of the container faces obliquely upward.

As one aspect, it is preferable that the transport vehicle further includes a lifting and lowering device configured to lift and lower the holding device,
in which when viewed in an up-down direction, a direction in which the pair of support portions are arranged is defined as a first direction, a direction orthogonal to the first direction is defined as a second direction, one side in the second direction is defined as a first side in the second direction, and the other side in the second direction is defined as a second side in the second direction,
the holding device further includes
a first guide portion configured to have a first guide surface facing the container and be disposed on the first side in the second direction with respect to the pair of support portions, and
a second guide portion configured to have a second guide surface facing the container and be disposed on the second side in the second direction with respect to the pair of support portions, and
when the holding device is lowered by the lifting and lowering device to approach the holding device to the container from an upper side, the first guide portion and the second guide portion are disposed such that at least one of the first guide surface and the second guide surface come into contact with the container.

According to this configuration, when the holding device is lowered by the lifting and lowering device to approach the holding device with respect to the container from the upper side, in a case in which the holding device is deviated in the second direction with respect to the container, only the guide surface of the guide portion on the side opposite to the side that is deviated (any one of the first guide surface and the second guide surface) comes into contact with the container so that the position of the holding device is able to be corrected. Therefore, the container is able to be appropriately held by the holding device.

As one aspect, it is preferable that the first guide surface is inclined toward the second side in the second direction as going upward, and the second guide surface is inclined toward the first side in the second direction as going upward.

According to this configuration, when the holding device is lowered by the lifting and lowering device to approach the container from the upper side, even in a case in which the holding device is deviated in the second direction with respect to the container, the holding device is able to be corrected to an appropriate position. Therefore, the container is able to be stably held at an appropriate position by the holding device.

As one aspect, it is preferable that the first guide portion and the second guide portion are disposed at different positions in the up-down direction.

According to this configuration, even in a case in which the container is supported in a posture in which an opening for taking in and out an accommodated object faces obliquely upward, as described above, the position of the holding device is able to be corrected to appropriately hold the container by the holding device.

As one aspect, it is preferable that when viewed in an up-down direction, the pressing portion is disposed between the pair of support portions.

According to this configuration, the container is able to be held more stably by pressing the container from above with the pressing portion and supporting the container from below with the support portion on both sides with the pressing portion interposed therebetween.

As one aspect, it is preferable that the holding device further includes
a holding main body portion configured to support the pair of support portions and the holding drive unit, and
a pressing support mechanism configured to movably support the pressing portion with respect to the holding main body portion along an up-down direction, and
the pressing support mechanism supports the pressing portion to bias the pressing portion to a lower side in a state in which the inclined support surface abuts against the pressed surface in a state in which the pair of supported portions are supported by the pair of support portions.

According to this configuration, for example, even when the position of the container in the up-down direction with respect to the holding device is slightly changed during the transport, the pressing portion is biased downward, so that the state of pressing the container from above with the pressing portion is able to be appropriately maintained. Therefore, the container is able to be held more stably.

As one aspect, it is preferable that a holding proper range is a range of a position of the holding device in an up-down direction in which the pair of support portions are able to support the pair of supported portions by changing from the holding release posture to the holding posture, and the holding device further includes a detection device configured to detect whether the holding device is within the holding proper range based on a position of the pressing portion.

According to this configuration, it is possible to detect whether the position of the holding device in the up-down direction is within the holding proper range based on the position of the pressing portion that is movable along the up-down direction. Therefore, for example, in a case in which the position of the holding device in the up-down direction deviates from the holding proper range, an opportunity for correcting the position is able to be obtained. As a result, the holding operation of the container by the holding device is able to be appropriately performed.

As one aspect, it is preferable that the container has an opening for taking in and out an accommodated object on a side surface, the holding device further includes a shielding member configured to change a posture between a closed posture in which the shielding member faces the opening at least partially in a state in which the pair of support portions support the pair of supported portions and an opened posture in which the shielding member does not face the opening, and the shielding member is configured to be in the closed posture as the pair of support portions are in the holding posture and to be in the opened posture as the pair of support portions are in the holding release posture by being interlocked to the posture change of the pair of support portions.

According to this configuration, by putting the shielding member into the closed posture, the opening is able to be covered at least partially by the shielding member, and flying out of the accommodated object from the container is able to be restricted. In addition, by interlocking the posture change between the closed posture and the opened posture of the shielding member to the posture change between the holding posture and the holding release posture of the pair of support portions, flying out of the accommodated object from the container is able to be restricted while holding the container by the holding device with a relatively simple configuration.

The transport vehicle according to the present disclosure may exhibit at least one of the above-described effects.

What is claimed is:

1. A transport vehicle that transports a container comprising a pair of supported portions and a pressed portion, the transport vehicle, comprising:
a holding device configured to hold the container, and
wherein the holding device comprises:
a pair of support portions configured to respectively support the pair of supported portions,
a holding drive unit configured to change a posture of the pair of support portions between a holding posture for holding the container and a holding release posture for releasing the holding of the container, and
a pressing portion configured to press the pressed portion,
the support portion has an inclined support surface and supports a supported surface of the supported portion by the inclined support surface,
the pressing portion has an inclined pressing surface and presses a pressed surface of the pressed portion on the inclined pressing surface, and
the inclined pressing surface is provided to be parallel to the pressed surface in a state in which the supported surface is supported by the inclined support surface.

2. The transport vehicle according to claim 1, further comprising:
a lifting and lowering device configured to lift and lower the holding device,
wherein when viewed in an up-down direction, a direction in which the pair of support portions are arranged is defined as a first direction, a direction orthogonal to the first direction is defined as a second direction, one side in the second direction is defined as a first side in the second direction, and the other side in the second direction is defined as a second side in the second direction,
wherein the holding device further comprises:
a first guide portion configured to have a first guide surface facing the container and be disposed on the first side in the second direction with respect to the pair of support portions, and
a second guide portion configured to have a second guide surface facing the container and be disposed on the second side in the second direction with respect to the pair of support portions, and
when the holding device is lowered by the lifting and lowering device to approach the holding device to the container from an upper side, the first guide portion and the second guide portion are disposed such that at least one of the first guide surface and the second guide surface come into contact with the container.

3. The transport vehicle according to claim 2,
wherein the first guide surface is inclined toward the second side in the second direction as going upward, and
wherein the second guide surface is inclined toward the first side in the second direction as going upward.

4. The transport vehicle according to claim 2,
wherein the first guide portion and the second guide portion are disposed at different positions in the up-down direction.

5. The transport vehicle according to claim 1,
wherein when viewed in an up-down direction, the pressing portion is disposed between the pair of support portions.

6. The transport vehicle according to claim 1,
wherein the holding device further comprises:
a holding main body portion configured to support the pair of support portions and the holding drive unit, and
a pressing support mechanism configured to movably support the pressing portion with respect to the holding main body portion along an up-down direction, and
wherein the pressing support mechanism supports the pressing portion to bias the pressing portion to a lower side in a state in which the inclined support surface abuts against the pressed surface in a state in which the pair of supported portions are supported by the pair of support portions.

7. The transport vehicle according to claim 6,
wherein a holding proper range is a range of a position of the holding device in an up-down direction in which the pair of support portions are able to support the pair of supported portions by changing from the holding release posture to the holding posture, and
wherein the holding device further comprises a detection device configured to detect whether the holding device is within the holding proper range based on a position of the pressing portion.

8. The transport vehicle according to claim 1,
wherein the container has an opening for taking in and out an accommodated object on a side surface,
wherein the holding device further comprises a shielding member configured to change a posture between a closed posture in which the shielding member faces the opening at least partially in a state in which the pair of support portions support the pair of supported portions and an opened posture in which the shielding member does not face the opening, and
wherein the shielding member is configured to be in the closed posture as the pair of support portions are in the holding posture and to be in the opened posture as the pair of support portions are in the holding release posture by being interlocked to the posture change of the pair of support portions.
